(19) United States
(12) Patent Application Publication
(10) Pub. No.: US 2026/0358384 A1
(43) Pub. Date: Nov. 12, 2026

(54) DIGITAL QUANTUM VOLTMETER AND VOLTAGE MEASUREMENT METHOD

(71) Applicant: National Institute of Metrology, China, Beijing (CN)

(72) Inventors: Jianting ZHAO, Beijing (CN); Yaqiong FU, Beijing (CN); Jifeng QU, Beijing (CN); Taotao SUI, Beijing (CN); Yunfeng LU, Beijing (CN); Lushuai QIAN, Beijing (CN); Changwei ZHAI, Beijing (CN)

(21) Appl. No.: 19/275,322

(22) Filed: Jul. 21, 2025

(30) Foreign Application Priority Data
May 8, 2025 (CN) 202510585046.2

(51) Int. Cl. G01R 19/25; G01R 19/00; H03K 3/0233

(52) U.S. Cl. CPC G01R 19/2506; G01R 19/0038; G01R 19/0053; H03K 3/02337

(57) ABSTRACT

The application provides a digital quantum voltmeter and a voltage measurement method, and relates to the field of quantum electrical measurement. The digital quantum voltmeter includes a quantum voltage reference device, an integrator, a hysteresis comparator, and a controller; where the controller is connected to an output terminal of the hysteresis comparator and an input terminal of the quantum voltage reference device, and the controller is configured to control a polarity of an output voltage of the quantum voltage reference device based on a polarity of an output voltage of the hysteresis comparator; and the integrator includes an input terminal connected to a tested voltage and an output terminal of the quantum voltage reference device, and an output terminal connected to an input terminal of the hysteresis comparator. The application can achieve a zero-traceability-chain configuration to improve voltage measurement accuracy.

### CROSS REFERENCE TO RELATED APPLICATION

This patent application claims the benefit and priority of Chinese Patent Application No. 202510585046.2, filed with the China National Intellectual Property Administration on May 8, 2025, the disclosure of which is incorporated by reference herein in its entirety as part of the present application.

### TECHNICAL FIELD

The present disclosure relates to the field of quantum electrical measurement, and in particular, to a digital quantum voltmeter and a voltage measurement method.

### BACKGROUND

A digital voltmeter is the core of the digital multimeter. In the electromagnetic metrology traceability system, the high-precision digital voltmeter is an important part in the traceability chain from a standard voltage source to a voltage reference.

At present, the digital voltmeter based on the conventional electronic technology has a maximum resolution of 8.5 digits. This 8.5-digit multimeter typically serves as secondary electrical metrology standards. In this context, the presence of redundant link in the metrological traceability chain becomes a problem that need to be addressed to improve the accuracy of electrical measurement. However, the existing highest-precision digital multimeter also requires a traceability chain, and cannot achieve a zero-traceability-chain configuration.

### SUMMARY

The purpose of the present disclosure is to provide a digital quantum voltmeter and a voltage measurement method, which can achieve a zero-traceability-chain configuration and improve voltage measurement accuracy.

To achieve the above objective, the present disclosure provides the following solution: In a first aspect, the present disclosure provides a digital quantum voltmeter, including: a quantum voltage reference device, an integrator, a hysteresis comparator, and a controller; where the controller is connected to an output terminal of the hysteresis comparator and an input terminal of the quantum voltage reference device, and the controller is configured to control a polarity of an output voltage of the quantum voltage reference device based on a polarity of an output voltage of the hysteresis comparator; and the integrator includes an input terminal connected to a tested voltage and an output terminal of the quantum voltage reference device, and an output terminal connected to an input terminal of the hysteresis comparator.

In an implementation, the digital quantum voltmeter further includes a quantum resistance reference device, where the input terminal of the integrator is connected to the tested voltage and the output terminal of the quantum voltage reference device through the quantum resistance reference device.

In an implementation, the digital quantum voltmeter further includes a reference voltage buffer, where the quantum resistance reference device is connected to the output terminal of the quantum voltage reference device through the reference voltage buffer.

In an implementation, the digital quantum voltmeter further includes an input voltage buffer, where the quantum resistance reference device is connected to the tested voltage through the input voltage buffer.

In an implementation, the digital quantum voltmeter further includes a slope amplifier, where the output terminal of the integrator is connected to the input terminal of the hysteresis comparator through the slope amplifier.

In an implementation, the digital quantum voltmeter further includes a charge release circuit, where an output terminal of the slope amplifier and the input terminal of the hysteresis comparator are each connected to a reference ground or the input terminal of the integrator through the charge release circuit.

In an implementation, the quantum resistance reference device includes a first quantum Hall resistor and a second quantum Hall resistor.

A first common terminal of the first quantum Hall resistor is connected to the tested voltage.

A first common terminal of the second quantum Hall resistor is connected to the output terminal of the quantum voltage reference device.

A second common terminal of the first quantum Hall resistor and a second common terminal of the second quantum Hall resistor are both connected to the input terminal of the integrator.

In an implementation, the digital quantum voltmeter further includes a first switch, where an input terminal of the input voltage buffer is connected to the tested voltage and the reference ground through the first switch.

In a second aspect, the present disclosure provides a voltage measurement method, applied to the above digital quantum voltmeter, where the voltage measurement method includes: after the tested voltage is input into the above digital quantum voltmeter, executing a first control step in M preset cycles, where the first control step is as follows: controlling, based on a polarity of a target voltage within a first time period, a polarity of a first-preset-value voltage output by the quantum voltage reference device; controlling the quantum voltage reference device to output a zero voltage within a second time period; controlling, within a third time period, the quantum voltage reference device to output the first-preset-value voltage with a same polarity as the tested voltage; and controlling the quantum voltage reference device to output a zero voltage within a fourth time period; where the first time period, the second time period, the third time period, and the fourth time period form one preset cycle; in an initial preset cycle, the target voltage is the tested voltage; in other preset cycles except for the initial preset cycle, the target voltage is an output voltage of the hysteresis comparator at a last moment of the fourth time period in a previous preset cycle; within the first time period in the initial preset cycle, the polarity of the first-preset-value voltage output by the quantum voltage reference device is opposite to the polarity of the target voltage, and within the first time period in the other preset cycles except for the initial preset cycle, the polarity of the first-preset-value voltage output by the quantum voltage reference device is the same as or opposite to the polarity of the target voltage; and M is an integer greater than 1;
controlling, based on the polarity of the output voltage of the hysteresis comparator at any moment before the end of an M-th preset cycle, the polarity of the output voltage of the quantum voltage reference device at the end of the M-th preset cycle;
executing a second control step within n clock cycles, where the second control step is as follows: reading a polarity of an output voltage of the hysteresis comparator in real time, when the polarity of the output voltage of the hysteresis comparator deviates at a t-th moment, determining, at a (t+d)-th moment, a duration of an output voltage of the quantum voltage reference device within a current clock cycle, and determining an output voltage of the quantum voltage reference device within a next clock cycle based on the output voltage of the quantum voltage reference device within the current clock cycle, where n is an integer greater than 1;
calculating a conversion voltage based on a length of the first time period, a length of the third time period, and a duration of an output voltage of the quantum voltage reference device within each clock cycle, and obtaining the conversion voltage of the tested voltage; and
obtaining an actual voltage of the tested voltage based on the conversion voltage of the tested voltage and a conversion voltage of the zero voltage, where the conversion voltage of the zero voltage is obtained by converting the tested voltage into a zero voltage and inputting the zero voltage into the above digital quantum voltmeter.

In an implementation, a conversion process of the zero voltage is as follows: after the zero voltage is input into the above digital quantum voltmeter, executing the first control step in the M preset cycles;
controlling, based on a polarity of an output voltage of the hysteresis comparator at any moment before the end of an M-th preset cycle, a polarity of an output voltage of the quantum voltage reference device at the end of the M-th preset cycle;
executing the second control step within the n clock cycles; and
calculating a conversion voltage based on a length of the second time period, the length of the third time period, and a duration of an output voltage of the quantum voltage reference device within each clock cycle, and obtaining the conversion voltage of the zero voltage.

According to specific embodiments provided in the present disclosure, the present disclosure has the following technical effects: the present disclosure provides a digital quantum voltmeter and a voltage measurement method, and compared with artifact standards, the quantum metrological standards exhibit significant advantages. Firstly, macroscopic quantum effects and physical constants objectively exist and will not vanish nor alter due to the damage of any physical artifact, thereby improving the stability and continuity of fundamental unit value preservation within the International System of Units (SI). Second, quantum metrological standards can be reproduced at any time and location through established physical techniques. By leveraging quantum metrological standards, the traditional pyramid-shaped metrology mode reliant on hierarchical calibration chains of artifact standards can be changed. It is expected to overcome the problems of gradually deteriorating measurement capabilities, periodic calibration of measuring instruments, and difficulty in tracing measurement results in special environments, thereby flattening the traceability chain and achieving single-step attainment of metrological accuracy. In related technologies, there are two ways to implement quantum metrology standards: one is a quantum voltage standard based on the Josephson effect that realizes the volt (V) as a unit of electromotive force, and the other is a quantum resistance standard device based on the quantum Hall effect that realizes the ohm (Ω) as a unit of electrical resistance. In general, measuring instruments or measuring devices require hierarchical traceability to the quantum standards. Taking the traceability chain of the highest-precision digital multimeter as an example, these devices also must undergo periodic verification or calibration using quantum voltage standards to maintain traceability within the calibration interval. This represents the shortest practical traceability chain in conventional metrology systems, yet it still necessitates at least one traceability link. By providing the quantum voltage reference device, the present disclosure can avoid the problem of additional periodic verification or calibration through a quantum voltage standard in related technologies, enabling traceability within the verification period and achieving a zero-traceability-chain configuration to improve voltage measurement accuracy.

### BRIEF DESCRIPTION OF THE DRAWINGS

To describe the technical solutions in the examples of this application or in the prior art more clearly, the following briefly describes the accompanying drawings required for the examples. Apparently, the accompanying drawings in the following description show merely some examples of this application, and a person of ordinary skill in the art may still derive other accompanying drawings from these accompanying drawings without creative efforts.

FIG. 1 is a schematic structural diagram of a digital quantum voltmeter according to an embodiment of the present disclosure.

FIG. 2 is a schematic structural diagram of a single pole double throw switch.

FIG. 3 is a schematic diagram of a connection method of a quantum Hall resistor provided in an embodiment of the present disclosure.

FIG. 4 is a sequence diagram of a first control step in a voltage measurement method provided in an embodiment of the present disclosure.

FIG. 5 a sequence diagram of a second control step in a voltage measurement method provided in an embodiment of the present disclosure.

Reference numerals: first switch—S1, Josephson junction array chip—JJA, input voltage buffer—A1, reference voltage buffer—A2, first low-temperature environment container—1, second low-temperature environment container—2, first quantum Hall resistor—R_{H1}, second quantum Hall resistor—R_{H2}, second switch—S2, first operational amplifier—A3, second operational amplifier—A4, basic comparator—A5, integration capacitor—Cᵢₙₜ, first resistor—R1, second resistor—R2, third resistor—R3, fourth resistor—R4, fifth resistor—R5, sixth resistor—R6, first diode—D1, second diode—D2, and negative voltage—V−.

### DETAILED DESCRIPTION OF THE EMBODIMENTS

The technical solutions in the embodiments of this application are clearly and completely described below with reference to the drawings in the embodiments of this application. Apparently, the described embodiments are only some rather than all of the embodiments of this application. All other embodiments obtained by a person of ordinary skill in the art based on the embodiments of the utility model without creative efforts shall fall within the protection scope of the utility model.

To make the above objectives, features, and advantages of the present disclosure more obvious and easy to understand, the present disclosure will be further described in detail with reference to the accompanying drawings and specific implementations.

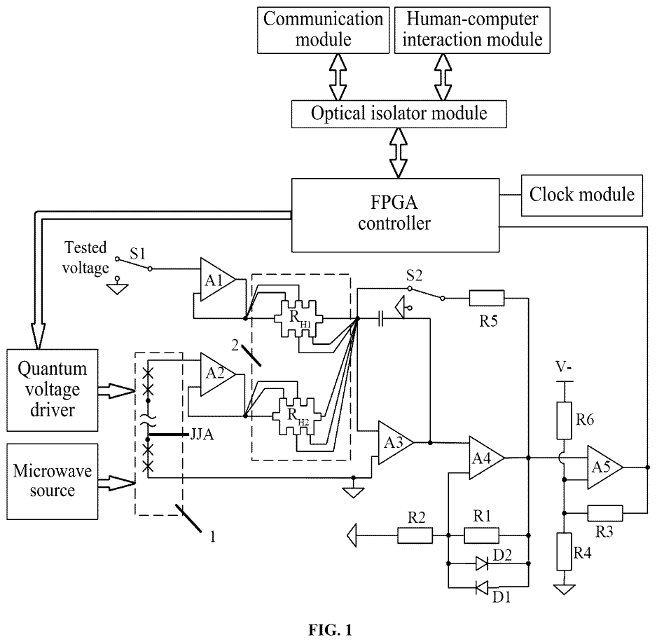

In an exemplary embodiment, as shown in FIG. 1, the present disclosure provides a digital quantum voltmeter, including: a quantum voltage reference device, an integrator, a hysteresis comparator, and a controller; where the controller is connected to an output terminal of the hysteresis comparator and an input terminal of the quantum voltage reference device, and the controller is configured to control a polarity of an output voltage of the quantum voltage reference device based on a polarity of an output voltage of the hysteresis comparator; and the integrator includes an input terminal connected to a tested voltage and an output terminal of the quantum voltage reference device, and an output terminal connected to an input terminal of the hysteresis comparator.

In another exemplary embodiment of the present disclosure, the digital quantum voltmeter further includes a clock module, a communication module, and a human-computer interaction module that are connected to the controller. Specifically, an output terminal of the clock module is connected to an input terminal of the controller, and the clock module is configured to provide a clock reference for timing calculation. The human-computer interaction module and the communication module are connected to the controller through an optical isolator module, the communication module is configured for data interaction with other devices, and an operator interacts with the controller through the human-computer interaction module. During practical application, the controller is a Field Programmable Gate Array (FPGA) controller.

In another exemplary embodiment of the present disclosure, the quantum voltage reference device further includes a quantum voltage driver, a microwave source, a Josephson junction array chip JJA, and a first low-temperature environment container 1; an output terminal of the controller is connected to an input terminal of the quantum voltage driver; the quantum voltage driver is configured to set a polarity and specific value of an output voltage of the quantum voltage reference device; output terminals of the quantum voltage driver and the microwave source are both connected to an input terminal of the Josephson junction array chip, and the Josephson junction array chip is disposed in the first low-temperature environment container 1. The quantum voltage reference device may be a Programmable Josephson Voltage Standard (PJVS) or a Josephson Arbitrary Waveform Synthesizer (JAWS), and the quantum voltage driver may be a PJVS quantum voltage driver or a JAWS quantum voltage driver.

In another exemplary embodiment of the present disclosure, the digital quantum voltmeter further includes a quantum resistance reference device, where the input terminal of the integrator is connected to the tested voltage and the output terminal of the quantum voltage reference device through the quantum resistance reference device.

In another exemplary embodiment of the present disclosure, the quantum resistance reference device includes a first quantum Hall resistor R_{H1} and a second quantum Hall resistor R_{H2}, and a first common terminal of the first quantum Hall resistor R_{H1} is connected to the tested voltage. A first common terminal of the second quantum Hall resistor R_{H2} is connected to the output terminal of the quantum voltage reference device. A second common terminal of the first quantum Hall resistor R_{H1} and a second common terminal of the second quantum Hall resistor R_{H2} are both connected to the input terminal of the integrator.

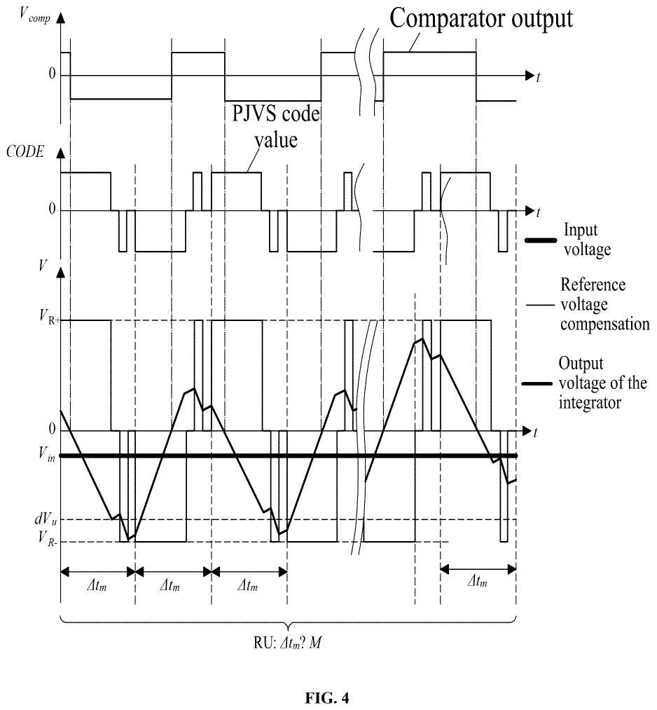

In another exemplary embodiment of the present disclosure, as shown in FIG. 3, the first common terminal of the first quantum Hall resistor R_{H1} is formed by shorting a first current electrode of the first quantum Hall resistor R_{H1} and multiple clockwise-adjacent voltage electrodes to a single point; the first common terminal of the second quantum Hall resistor R_{H2} is formed by shorting a first current electrode of the second quantum Hall resistor R_{H2} and multiple clockwise-adjacent voltage electrodes to a single point; the second common terminal of the first quantum Hall resistor R_{H1} is formed by shorting a second current electrode of the first quantum Hall resistor R_{H1} and multiple clockwise-adjacent voltage electrodes to a single point; and the second common terminal of the second quantum Hall resistor R_{H2} is formed by shorting a second current electrode of the second quantum Hall resistor R_{H2} and multiple clockwise-adjacent voltage electrodes to a single point.

The reason for the above design is as follows: the usage state of the quantum Hall resistors must strictly meet requirements of a four-terminal resistor in order to completely avoid errors introduced by their leads. However, when multiple V/I branches of the integrator are added together at an inverting input terminal of the reference voltage buffer A2, the four probe method definition of resistors cannot be met (that is, all current passing through the resistors flows through the current lead, and no current passes through the voltage lead). With the above connection method, based on the Ricketts-Kemeny model of the quantum Hall resistor, the relationship between single-terminal lead current, lead resistance, and AB-terminal equivalent resistance is established as formula (1).

$$\{ \begin{matrix}{I}_{f} = \frac{I}{1 + \frac{{ε}_{f}}{2 ( 1 + \frac{{ε}_{s}}{2} )} + 1 + \frac{{ε}_{f} {ε}_{s}}{4 ( 1 + \frac{{ε}_{s}}{2} ) ( 1 + \frac{{ε}_{t}}{2} )}} \\ {I}_{s} = \frac{{ε}_{f}}{2 ( 1 + \frac{{ε}_{s}}{2} )} {I}_{f} \\ {I}_{t} = \frac{{ε}_{s}}{2 ( 1 + \frac{{ε}_{t}}{2} )} {I}_{s} \\ {R}_{AB} = {R}_{H} ( 1 + \frac{{I}_{t}}{I} \cdot \frac{{ε}_{t}}{2} )\end{matrix} . \qquad ( 1 )$$

In the formula, I_{f}, Iₛ, and Iₜ are currents of three lead branches respectively; ε_{f}, εₛ, and εₜ are relative values of the resistance of the three lead branches to the quantum Hall resistor (R_{H}/2), respectively; R_{AB} is a resistor between nodes A and B; and I is a total current flowing into the nodes.

Formula (2) is further derived from the formula (1):

$$I = \frac{{V}_{AB}}{{R}_{AB}} = \frac{{V}_{AB}}{{R}_{H}} ( 1 - \frac{{ε}_{f} {ε}_{s} {ε}_{t}}{8} + O ( ε ) ) . \qquad ( 2 )$$

In the formula, V_{AB} is a voltage between nodes A and B; O(ε) indicates a high-order error term that can be ignored; the formula (2) shows that: if a relative value of the lead resistance to the quantum Hall resistor (R_{H}/2) is the order of magnitude of 10⁻⁴, then an error introduced by the equivalent resistor R_{AB} connected as shown in FIG. 3 compared to the quantum Hall resistor R_{H} is the order of magnitude of 10⁻¹², which can be completely ignored. The above is an analysis of the connection between two voltage electrodes and a current electrode. In fact, adjacent three voltage electrodes can also be connected to the current electrode to further reduce lead resistance errors.

In another exemplary embodiment of the present disclosure, the quantum resistance reference device further includes a second low-temperature environment container 2, and the first quantum Hall resistor R_{H1} and the second quantum Hall resistor R_{H2} are disposed in the second low-temperature environment container 2. The first low-temperature environment container 1 and the second low-temperature environment container 2 can be set to a same low temperature of 4.2K, or select different low-temperature temperatures according to differences in the types of devices used. Due to the different magnetic field environments required for the operations of the Josephson junction array chip and the quantum Hall resistors, the first low-temperature environment container 1 and the second low-temperature environment container 2 cannot be merged.

In another exemplary embodiment of the present disclosure, the integrator includes a first operational amplifier A3 and an integration capacitor Cᵢₙₜ. The second common terminal of the first quantum Hall resistor R_{H1} and the second common terminal of the second quantum Hall resistor R_{H2} are both connected to an inverting input terminal of the first operational amplifier A3 and an input terminal of the integration capacitor Cᵢₙₜ in the integrator; and the first operational amplifier A3 includes an in-phase input terminal connected to a reference ground, and an output terminal connected to an output terminal of the integration capacitor Cᵢₙₜ. The first operational amplifier A3 should adopt an amplifier having high input impedance and low noise, such as LT1001. The integration capacitor Cᵢₙₜ should adopt a capacitor with low temperature drift and low temperature coefficient, such as a polystyrene capacitor.

In another exemplary embodiment of the present disclosure, the digital quantum voltmeter further includes an input voltage buffer A1, where the quantum resistance reference device is connected to the tested voltage through the input voltage buffer A1. Specifically, the input voltage buffer A1 includes an in-phase input terminal connected to the tested voltage, and an inverting input terminal and an output terminal both connected to the first common terminal of the first quantum Hall resistor R_{H1}. In practical applications, the input voltage buffer A1 can generally be constructed using an operational amplifier having stable unit gain. The purpose of setting the input voltage buffer A1 is to achieve impedance matching. Specifically, the input impedance of a subsequent stage is increased relative to the tested voltage, and the output impedance of a preceding stage is decreased relative to the first quantum Hall resistor.

In another exemplary embodiment of the present disclosure, the digital quantum voltmeter further includes a first switch S1, where an input terminal of the input voltage buffer A1 is connected to the tested voltage and the reference ground through the first switch S1. Specifically, the first switch S1 may be a single pole double throw switch, and an input terminal of the tested voltage is connected to the in-phase input terminal of the input voltage buffer A1 through the single pole double throw switch. Setting this switch is to eliminate measurement errors caused by offset voltage, thermoelectric potential, etc. in the measurement process. During measurement, the tested voltage and a reference ground potential are connected to a subsequent circuit through the first switch S1, and are measured and read separately. The two readings are subjected to subtraction, so as to eliminate measurement errors caused by offset voltage, thermoelectric potential, etc.

In another exemplary embodiment of the present disclosure, the digital quantum voltmeter further includes a reference voltage buffer A2, where the quantum resistance reference device is connected to the output terminal of the quantum voltage reference device through the reference voltage buffer A2. Specifically, the output terminal of the quantum voltage reference device is connected to an in-phase input terminal of the reference voltage buffer A2, and an inverting input terminal and an output terminal of the reference voltage buffer A2 are both connected to the first common terminal of the Second quantum Hall resistor R_{H2}.

In another exemplary embodiment of the present disclosure, the digital quantum voltmeter further includes a slope amplifier, where the output terminal of the integrator is connected to the input terminal of the hysteresis comparator through the slope amplifier, and the slope amplifier can make the hysteresis comparator more sensitive in determining the polarity of the output voltage of the integrator.

In another exemplary embodiment of the present disclosure, the slope amplifier includes a second operational amplifier A4, a first resistor R1, a second resistor R2, a first diode D1, and a second diode D2. An in-phase input terminal of the second operational amplifier A4 is connected to the output terminal of the first operational amplifier A3. An inverting input terminal of the second operational amplifier A4 is connected to the reference ground through the second resistor R2. The first resistor R1, the first diode D1, and the second diode D2 are connected in parallel between the inverting input terminal and an output terminal of the second operational amplifier A4, where the first diode D1 and the second diode D2 are configured in opposite polarity directions. The slope amplifier is configured to, when the output voltage of the integrator is within a ±0.7V voltage limit determined by the first diode D1 and the second diode D2, amplify the output voltage of the integrator using an amplification factor determined by the second resistor R2 and the first resistor R1, thereby enhancing the resolution of the hysteresis comparator in discriminating the output voltage of the integrator. If the output voltage of the integrator exceeds the ±0.7V voltage limit determined by the first diode D1 and the second diode D2, the amplification factor is approximately 1 to avoid saturation.

In another exemplary embodiment of the present disclosure, the digital quantum voltmeter further includes a charge release circuit, where an output terminal of the slope amplifier and the input terminal of the hysteresis comparator are each connected to the reference ground or the input terminal of the integrator through the charge release circuit.

In another exemplary embodiment of the present disclosure, the charge release circuit includes a second switch S2 and a fifth resistor R5. The fifth resistor R5 includes one terminal connected to the input terminal of the integration capacitor Cᵢₙₜ and the reference ground through the second switch S2, and the other terminal connected to the output terminal of the slope amplifier. Specifically, the other terminal of the fifth resistor R5 is connected to the output terminal of the second operational amplifier A4, one terminal of the first resistor R1, the output terminal of the second diode D2, and the input terminal of the first diode D1. When the device is in a non-measuring state, the second switch S2 can connect the input terminal of the integration capacitor Cᵢₙₜ to the output terminal of the slope amplifier, thereby avoiding integrator saturation.

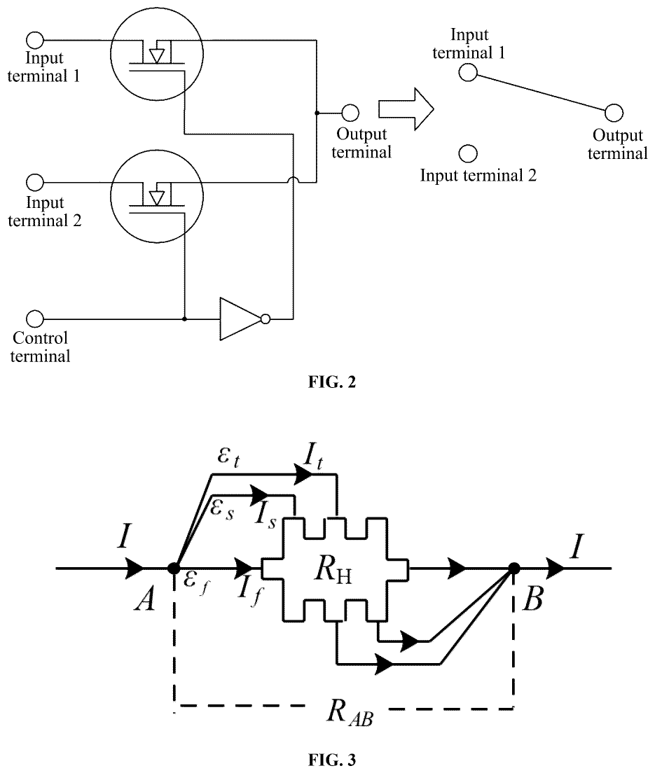

In another exemplary embodiment of the present disclosure, the first switch S1 and the second switch S2 are single pole double throw switches and have a same structure. As shown in FIG. 2, the single pole double throw switch consists of two semiconductor switching transistors. Two electrodes of the two semiconductor switching transistors serve as input terminal 1 and input terminal 2 respectively, and the other two electrodes of the two semiconductor switching transistors are connected to serve as an output terminal. Control signals of the two semiconductor switching transistors are complementary signals. The semiconductor switch can a be metal-oxide-semiconductor field-effect transistor (MOSFET), a junction field-effect transistor (JFET), or an integrated analog switch.

In another exemplary embodiment of the present disclosure, the hysteresis comparator includes: a basic comparator A5, a third resistor R3, a fourth resistor R4, and a sixth resistor R6, where the fourth resistor R4 and the sixth resistor R6 divide a negative voltage V−, and a dividing point is connected to an in-phase input terminal of the basic comparator A5; the dividing point is also connected to an output terminal of the basic comparator A5 through the third resistor R3; the sixth resistor R6 includes one terminal connected to the negative voltage V−, and the other terminal connected to the in-phase input terminal of the basic comparator A5, one terminal of the third resistor R3, and one terminal of the fourth resistor R4; the other terminal of the fourth resistor R4 is connected to the reference ground; the other terminal of the third resistor R3 is connected to the output terminal of the basic comparator A5 and the input terminal of the controller; and an inverting input terminal of the basic comparator A5 is connected to the output terminal of the second operational amplifier A4. Using the hysteresis comparator can avoid the oscillation of a common comparator generated near the zero crossing point.

The present disclosure directly traces a voltage measurement result back to the electrical quantum standards, which can shorten the voltage traceability chain and greatly improve the measurement accuracy.

An embodiment of the present disclosure further provides a voltage measurement method applied to the above digital quantum voltmeter. The voltage measurement method is executed by the controller and specifically includes the following steps.

Step 101: after the tested voltage is input into the above digital quantum voltmeter, a first control step is executed in M preset cycles, where the first control step is as follows: controlling, based on a polarity of a target voltage within a first time period, a polarity of a first-preset-value voltage output by the quantum voltage reference device; controlling the quantum voltage reference device to output a zero voltage within a second time period; controlling, within a third time period, the quantum voltage reference device to output the first-preset-value voltage with a same polarity as the tested voltage; and controlling the quantum voltage reference device to output a zero voltage within a fourth time period; where the first time period, the second time period, the third time period, and the fourth time period form one preset cycle; in an initial preset cycle, the target voltage is the tested voltage; in other preset cycles except for the initial preset cycle, the target voltage is an output voltage of the hysteresis comparator at a last moment of the fourth time period in a previous preset cycle; within the first time period in the initial preset cycle, the polarity of the first-preset-value voltage output by the quantum voltage reference device is opposite to the polarity of the target voltage, and within the first time period in the other preset cycles except for the initial preset cycle, the polarity of the first-preset-value voltage output by the quantum voltage reference device is the same as or opposite to the polarity of the target voltage; and M is an integer greater than 1.

Step 102: based on a polarity of an output voltage of the hysteresis comparator at any moment before the end of an M-th preset cycle, a polarity of an output voltage of the quantum voltage reference device at the end of the M-th preset cycle is controlled. The polarity of the output voltage of the quantum voltage reference device remains unchanged in a following time period, and the following steps are executed during a clock cycle in the following time period.

Step 103: a second control step is executed within n clock cycles, where the second control step is as follows: reading a polarity of an output voltage of the hysteresis comparator in real time, when the polarity of the output voltage of the hysteresis comparator deviates at a t-th moment, determining, at a (t+d)-th moment, a duration of an output voltage of the quantum voltage reference device within a current clock cycle, and determining an output voltage of the quantum voltage reference device within a next clock cycle based on the output voltage of the quantum voltage reference device within the current clock cycle, where n is an integer greater than 1.

Step 104: a conversion voltage is calculated based on a length of the first time period, a length of the third time period, and a duration of an output voltage of the quantum voltage reference device within each clock cycle, and the conversion voltage of the tested voltage is obtained.

Step 105: an actual voltage of the tested voltage is obtained based on the conversion voltage of the tested voltage and a conversion voltage of the zero voltage, where the conversion voltage of the zero voltage is obtained by converting the tested voltage into a zero voltage and inputting the zero voltage into the above digital quantum voltmeter.

In an exemplary embodiment, a conversion process of the zero voltage is as follows.

Step 201: after the zero voltage is input into the above digital quantum voltmeter, the first control step is executed in the M preset cycles.

Step 202: based on a polarity of an output voltage of the hysteresis comparator at any moment before the end of the M-th preset cycle, a polarity of an output voltage of the quantum voltage reference device at the end of the M-th preset cycle is controlled.

Step 203: the second control step is executed within the n clock cycles.

Step 204: a conversion voltage is calculated based on a length of the second time period, the length of the third time period, and a duration of an output voltage of the quantum voltage reference device within each clock cycle, and the conversion voltage of the zero voltage is obtained.

In an exemplary embodiment, step 101 specifically includes step 1-1: the following actions are synchronously executed: switch the first switch S1 to the tested voltage, such that after passing through the input voltage buffer A1, the tested voltage generates an integral current on the first quantum Hall resistor R_{H1}; switch the second switch S2 to the reference ground to activate the integrator; set the polarity of the output voltage of the quantum voltage reference device in a first stage to be opposite to the polarity of the tested voltage, with a voltage value of V_{R}, and output a set voltage under the drive of the quantum voltage driver and the microwave source; and after passing through the reference voltage buffer A2, the tested voltage generates another integral current on the second quantum Hall resistor R_{H2}.

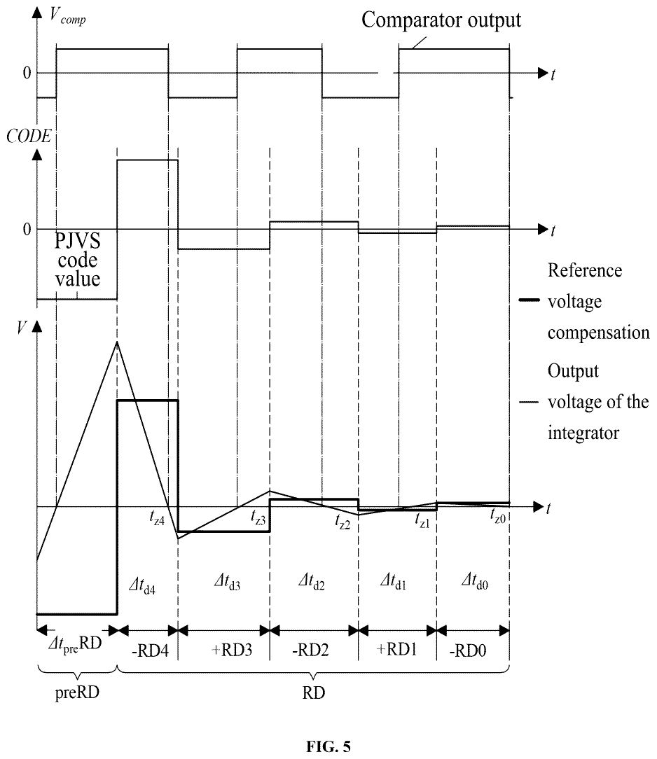

As shown in FIG. 4, step 1-2: In a first preset cycle, the following actions are separately executed in four stages, namely, the above four time periods: in a first stage, the quantum voltage reference device outputs a voltage set in a previous step, and this time period is denoted as Δₜₘ₁; in a second stage, the quantum voltage reference device outputs zero voltage, and this time period is denoted as Δₜₘ₂; in a third stage, the quantum voltage reference device outputs a voltage with a same amplitude as and a polarity opposite to the first stage, and this time period is denoted as Δₜₘ₃; in a fourth stage, the quantum voltage reference device outputs zero voltage, and this time period is denoted as Δₜₘ₄. Before Δₜₘ₄.ends, the polarity of the output voltage of the hysteresis comparator are read, and a polarity of an output voltage of the quantum voltage reference device is predicted within a next preset cycle based on the polarity of the output voltage of the hysteresis comparator. Specifically: if the inverting input terminal of the basic comparator A5 is connected to the output terminal of the second operational amplifier A4, and the in-phase input terminal of the basic comparator A5 is connected to the other terminal of the sixth resistor R6, one terminal of the third resistor R3, and one terminal of the fourth resistor R4, then it is predicted that the polarity of the output voltage of the quantum voltage reference device within the next preset cycle is opposite to the read polarity of the output voltage of the hysteresis comparator; if the in-phase input terminal of the basic comparator A5 is connected to the output terminal of the second operational amplifier A4, and the inverting input terminal of the basic comparator A5 is connected to the other terminal of the sixth resistor R6, one terminal of the third resistor R3, and one terminal of the fourth resistor R4, then it is predicted that the polarity of the output voltage of the quantum voltage reference device within the next preset cycle is the same as the read polarity of the output voltage of the hysteresis comparator.

### Step 1-3: The Step 1-2 is Repeated M Times.

In an exemplary embodiment, as shown in FIG. 5, in the preRD stage, step 102 specifically includes step 1-4: the polarity of the output voltage of the hysteresis comparator is read before a last preset cycle ends, and the polarity of the output voltage of the quantum voltage reference device is regulated when the last preset cycle ends based on the polarity of the output voltage of the hysteresis comparator, such that the output voltage of the integrator changes in the next stage in a direction in which the polarity of the output voltage of the hysteresis comparator is driven to change, where the output voltage of the quantum voltage reference device at this stage is denoted as V_{Rn}.

In an exemplary embodiment, as shown in FIG. 5, in the RD stage, step 103 specifically includes step 1-5: the polarity of the output voltage of the hysteresis comparator in each clock cycle is read, when the polarity of the output voltage of the hysteresis comparator flips, after a delay of d clocks, a duration of the output voltage of the quantum voltage reference device in a current clock cycle is recorded, and the output voltage of the quantum voltage reference device in the next clock cycle is calculated according to the formula

$${V}_{R ( i - 1 )} = - \frac{{V}_{R ( i )}}{B} ,$$

and the quantum voltage reference device is controlled to change the output voltage in the next clock cycle, where V_{R (i)} represents the output voltage of the quantum voltage reference device in an i-th clock cycle, and n and B are positive integers greater than 1, which have no practical significance; and i has an initial value of n.
Step 1-6: The Step 1-5 is Repeated, and i is Decreased Each Time Until i=1.

In an exemplary embodiment, step 104 specifically includes step 1-7: the second switch S2 of the charge release circuit is switched to the input terminal of the integration capacitor Cᵢₙₜ, and integration is terminated and a residual charge of the integrator is released. At the same time, the conversion voltage is calculated to the formula according

$${U}_{i n} = \frac{( Δ {t}_{m 1} + Δ {t}_{m 3} ) ( {M}_{+} - {M}_{-} ) + {{\sum }_{i = n}}^{1} \frac{{t}_{i}}{{B}^{n - i}}}{( Δ {t}_{m 1} + Δ {t}_{m 3} ) ( {M}_{+} + {M}_{-} )}$$

to obtain the conversion voltage of the tested voltage, where tᵢ represents a duration of the output voltage of the quantum voltage reference device in the i-th clock cycle, Uᵢₙ represents the conversion voltage, M₊ is a count that an output polarity of a quantum voltage in the first stage in M preset cycles is positive, M_ is a count that the output polarity of the quantum voltage in the first stage in the M preset cycles is negative, and the sum of M₊ and M_ is M.

In an exemplary embodiment, step 105 specifically includes: the conversion voltage of the zero voltage is subtracted from the conversion voltage of the tested voltage to obtain the actual voltage of the tested voltage.

In an exemplary embodiment, before step 201, the voltage measurement method further includes step 2-1: the following actions are synchronously executed: switch the first switch S1 to an input reference ground, switch the second switch S2 to the reference ground, and set the polarity of the output voltage of the quantum voltage reference device to be opposite to the polarity of the tested voltage, with a voltage value of V_{R}.

In an exemplary embodiment, when parameters B and n are selected, it should be ensured that V_{R0} is an integer multiple of the output voltage LSB of the quantum voltage reference device; when d is selected, it should be ensured that the output voltage V_{R0} of the quantum voltage reference device within d time has an integral voltage greater than an input noise limit of the hysteresis comparator; and the preset cycle adopts the clock cycle provided by the clock module as a basic unit.

The technical characteristics of the above embodiments can be employed in arbitrary combinations. To provide a concise description of these embodiments, all possible combinations of all the technical characteristics of the above embodiments may not be described; however, these combinations of the technical characteristics should be construed as falling within the scope defined by the specification as long as no contradiction occurs.

Several examples are used herein for illustration of the principles and implementations of this application. The description of the foregoing examples is used to help illustrate the method of this application and the core principles thereof. In addition, those of ordinary skill in the art can make various modifications in terms of specific implementations and scope of application in accordance with the teachings of this application. In conclusion, the content of the present specification shall not be construed as a limitation to this application.

What is claimed is:

1: A digital quantum voltmeter, comprising:
a quantum voltage reference device, a quantum resistance reference device, an integrator, a hysteresis comparator, and a controller;
wherein, the controller is connected to an output terminal of the hysteresis comparator and an input terminal of the quantum voltage reference device, and the controller is configured to control a polarity of an output voltage of the quantum voltage reference device based on a polarity of an output voltage of the hysteresis comparator;
the integrator comprises an input terminal connected to a tested voltage and an output terminal of the quantum voltage reference device, and an output terminal connected to an input terminal of the hysteresis comparator; and
the input terminal of the integrator is connected to the tested voltage and the output terminal of the quantum voltage reference device through the quantum resistance reference device.

2. (canceled)

3: The digital quantum voltmeter according to claim 1, wherein the digital quantum voltmeter further comprises a reference voltage buffer, and the quantum resistance reference device is connected to the output terminal of the quantum voltage reference device through the reference voltage buffer.

4: The digital quantum voltmeter according to claim 1, wherein the digital quantum voltmeter further comprises an input voltage buffer, and the quantum resistance reference device is connected to the tested voltage through the input voltage buffer.

5: The digital quantum voltmeter according to claim 1, wherein the digital quantum voltmeter further comprises a slope amplifier, and the output terminal of the integrator is connected to the input terminal of the hysteresis comparator through the slope amplifier.

6: The digital quantum voltmeter according to claim 5, wherein the digital quantum voltmeter further comprises a charge release circuit, and an output terminal of the slope amplifier and the input terminal of the hysteresis comparator are each connected to a reference ground or the input terminal of the integrator through the charge release circuit.

7: The digital quantum voltmeter according to claim 1, wherein the quantum resistance reference device comprises a first quantum Hall resistor and a second quantum Hall resistor;
a first common terminal of the first quantum Hall resistor is connected to the tested voltage;
a first common terminal of the second quantum Hall resistor is connected to the output terminal of the quantum voltage reference device; and
a second common terminal of the first quantum Hall resistor and a second common terminal of the second quantum Hall resistor are both connected to the input terminal of the integrator.

8: The digital quantum voltmeter according to claim 4, wherein the digital quantum voltmeter further comprises a first switch, and an input terminal of the input voltage buffer is connected to the tested voltage and the reference ground through the first switch.

9: A voltage measurement method, applied to the digital quantum voltmeter according to claim 1, and comprising:
after a tested voltage is input into the digital quantum voltmeter according to claim 1,
executing a first control step in M preset cycles, wherein the first control step is as follows: controlling, based on a polarity of a target voltage within a first time period, a polarity of a first-preset-value voltage output by the quantum voltage reference device; controlling the quantum voltage reference device to output a zero voltage within a second time period; controlling, within a third time period, the quantum voltage reference device to output the first-preset-value voltage with a same polarity as the tested voltage; and controlling the quantum voltage reference device to output a zero voltage within a fourth time period; wherein the first time period, the second time period, the third time period, and the fourth time period form one preset cycle; in an initial preset cycle, the target voltage is the tested voltage; in other preset cycles except for the initial preset cycle, the target voltage is an output voltage of the hysteresis comparator at a last moment of the fourth time period in a previous preset cycle; within the first time period in the initial preset cycle, the polarity of the first-preset-value voltage output by the quantum voltage reference device is opposite to the polarity of the target voltage, and within the first time period in the other preset cycles except for the initial preset cycle, the polarity of the first-preset-value voltage output by the quantum voltage reference device is the same as or opposite to the polarity of the target voltage; and M is an integer greater than 1;
controlling, based on a polarity of an output voltage of the hysteresis comparator at any moment before the end of an M-th preset cycle, a polarity of an output voltage of the quantum voltage reference device at the end of the M-th preset cycle;
executing a second control step within n clock cycles, wherein the second control step is as follows: reading a polarity of an output voltage of the hysteresis comparator in real time, when the polarity of the output voltage of the hysteresis comparator deviates at a t-th moment, determining, at a (t+d)-th moment, a duration of an output voltage of the quantum voltage reference device within a current clock cycle, and determining an output voltage of the quantum voltage reference device within a next clock cycle based on the output voltage of the quantum voltage reference device within the current clock cycle, wherein n is an integer greater than 1;
calculating a conversion voltage based on a length of the first time period, a length of the third time period, and a duration of an output voltage of the quantum voltage reference device within each clock cycle, and obtaining the conversion voltage of the tested voltage; and
obtaining an actual voltage of the tested voltage based on the conversion voltage of the tested voltage and a conversion voltage of the zero voltage, wherein the conversion voltage of the zero voltage is obtained by converting the tested voltage into a zero voltage and inputting the zero voltage into the digital quantum voltmeter according to claim 1.

10: The voltage measurement method according to claim 9, wherein a conversion process of the zero voltage is as follows:
after the zero voltage is input into the digital quantum voltmeter according to claim 1,
executing the first control step in the M preset cycles;
controlling, based on the polarity of the output voltage of the hysteresis comparator at any moment before the end of the M-th preset cycle, the polarity of the output voltage of the quantum voltage reference device at the end of the M-th preset cycle;
executing the second control step within n clock cycles; and
calculating a conversion voltage based on a length of the second time period, the length of the third time period, and a duration of the output voltage of the quantum voltage reference device within each clock cycle, and obtaining the conversion voltage of the zero voltage.
